(19) United States
(12) Patent Application Publication
(10) Pub. No.: US 2008/0105869 A1
(43) Pub. Date: May 8, 2008

(54) PRINTED CIRCUIT BOARD FOR MOUNTING SEMICONDUCTOR DEVICE PACKAGE, AND METHOD OF TESTING AND FABRICATING SEMICONDUCTOR DEVICE PACKAGE USING THE SAME

(75) Inventor: Shin-Hyung KIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/935,119

(22) Filed: Nov. 5, 2007

(30) Foreign Application Priority Data
Nov. 6, 2006 (KR) 10-2006-109131

(51) Int. Cl. H01L 23/58; G01R 31/26; H05K 1/00; H01L 21/66

(52) U.S. Cl. 257/48; 174/250; 324/755; 438/15; 257/E23.023; 257/E21.531

(57) ABSTRACT

Provided is a printed circuit board for a semiconductor device. The printed circuit board includes an upper surface ball out structure configured the same as a ball array of a semiconductor device package mounted on the upper surface of the printed circuit board, and a lower surface ball out structure configured the same as a ball out structure of a lower board. The lower surface ball out structure is a standardized structure.

### CROSS-REFERENCE TO RELATED APPLICATIONS

This U.S. non-provisional patent application claims priority under 35 U.S.C. § 119 to Korean Patent Application No. 10-2006-109131, filed on Nov. 6, 2006, the entire contents of which are hereby incorporated by reference.

### BACKGROUND

1. Technical Field

This disclosure relates to a semiconductor device package, and more particularly, to a printed circuit board for mounting a semiconductor device package.

2. Description of the Related Art

Generally, to conduct an electrical characteristics test of a semiconductor chip of a semiconductor device package, the electrical characteristics test is performed with the semiconductor device package mounted on a test board connected to test equipment. In this case, a socket mounting test board is generally used as the test board.

Semiconductor devices are now being offered as application-specific devices. Thus, many semiconductor device package types having various functions are required. As a result, in order to test the electrical characteristics of semiconductor device packages, the cost and time expended to produce the test boards are gradually increasing because an assortment of sockets and test boards must be used.

Typically, one type of socket is mounted on the test board. Therefore, in order to test various types of semiconductor device packages, sockets and test boards suitable for the respective types of semiconductor device packages are needed. For example, respectively different sockets and test substrates must be used to perform the electrical characteristics test on a quad flat package (QFP) type semiconductor device package and on a ball grid array (BGA) type semiconductor device package. This is due to differences in the number (or the structure) of pins of the socket depending on the type of the semiconductor device package, and to the ensuing differences in the number of corresponding socket pin holes of the test board in which the pins of the socket are inserted. Accordingly, because a suitable socket and test board must be separately manufactured in order to conduct the electrical characteristics test for a typical semiconductor device package according to the type of the latter, a limitation in a decrease in the cost and time for testing the electrical characteristics of the semiconductor device package arises.

Furthermore, in order to manufacture a semiconductor device, the semiconductor device package that has passed the electrical characteristics test is mounted on a system board. Thus, in the manufacturing process of the semiconductor device, the system board suitable for the type of the semiconductor device package must be made separately, thereby complicating the manufacturing process and reducing yield. Embodiments address these and other disadvantages of the conventional art.

### SUMMARY

Some embodiments provide printed circuit boards for mounting semiconductor device packages with a variety of structures. Some embodiments also provide semiconductor device package testing methods using printed circuit boards for mounting semiconductor device packages with a variety of structures. Some embodiments further provide semiconductor device manufacturing methods using printed circuit boards for mounting semiconductor device packages with a variety of structures.

Some embodiments provide printed circuit boards for mounting semiconductor device packages. The printed circuit boards include: an upper surface ball out structure configured substantially the same as a ball array of a semiconductor device package mounted on an upper surface of the printed circuit board; and a lower surface ball out structure configured substantially the same as a ball out structure of a lower board, wherein the lower surface ball out structure is a standardized structure.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain inventive principles present in example embodiments. In the figures:

FIGS. 1A and 1B are top plan views of printed circuit boards for mounting semiconductor device packages according to some embodiments;

FIG. 2 is a bottom plan view of printed circuit boards for mounting semiconductor packages according to some embodiments;

FIGS. 3A and 3B are sectional views of FIGS. 1A and 1B taken along lines I-I′ and II-II′, respectively;

FIGS. 4A and 4B are sectional views of printed circuit boards for mounting semiconductor device packages according to some embodiments; and

FIGS. 5 through 8 are sectional views of printed circuit boards for mounting semiconductor device packages according to alternate embodiments.

### DETAILED DESCRIPTION

Preferred embodiments of the invention will be described below in more detail with reference to the accompanying drawings. The invention may, however, be embodied in different forms and should not be constructed as limited to the embodiments set forth herein. Rather, these embodiments are provided so that this disclosure will be thorough and complete, and will fully convey the scope of the present invention to those skilled in the art.

Because preferred embodiments are provided, the order of the reference numerals given in the description is not limited thereto. In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Hereinafter, an exemplary embodiment of the present invention will be described with the accompanying drawings.

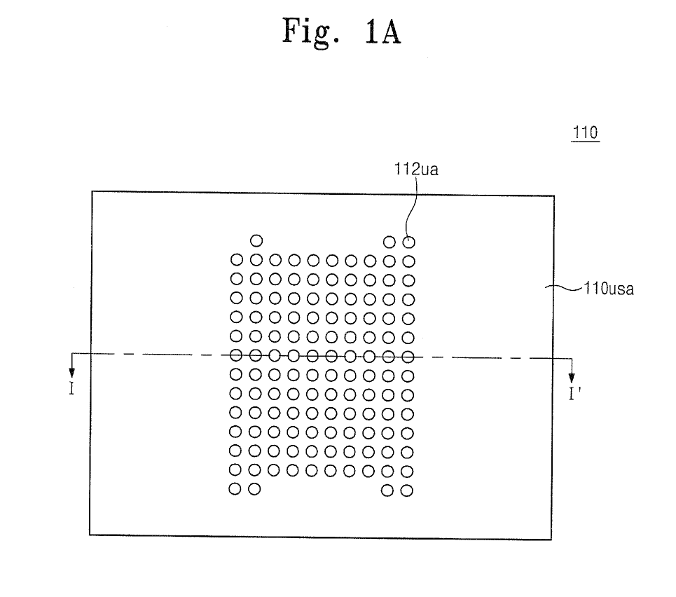

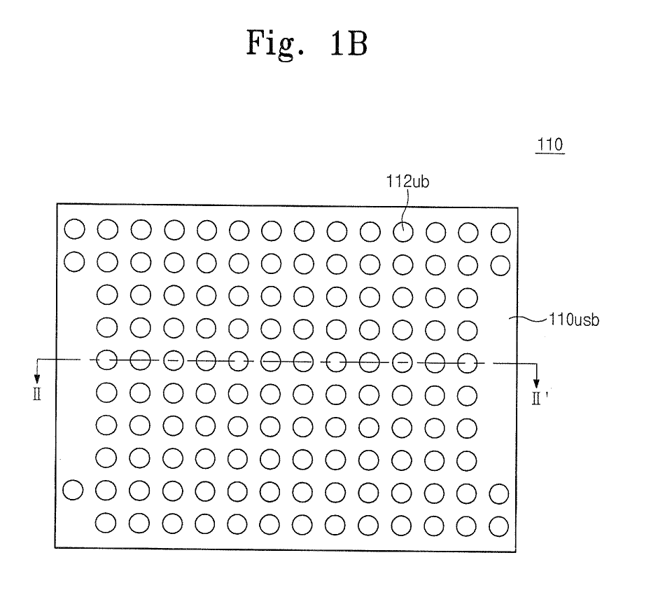

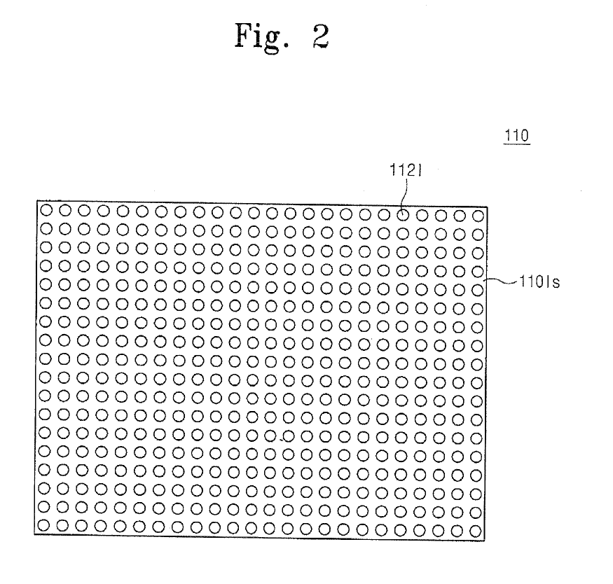

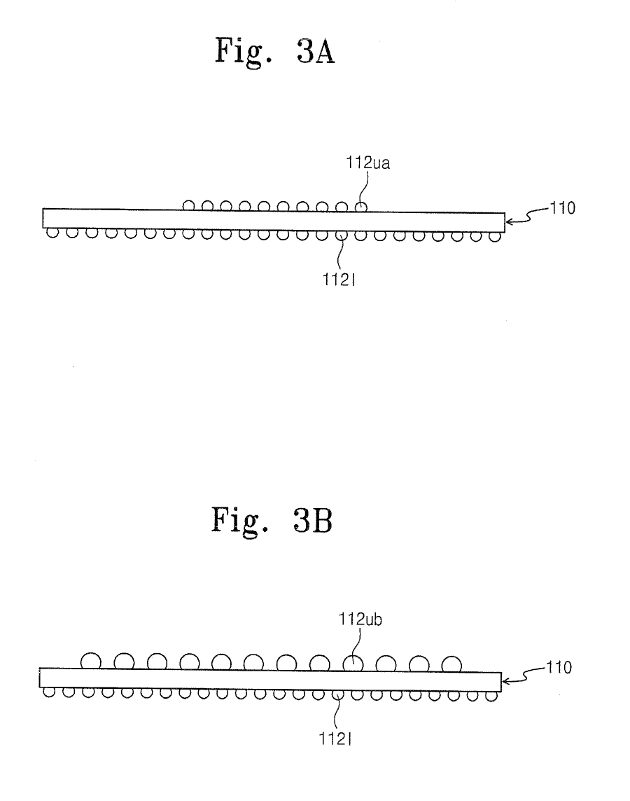

FIGS. 1A and 1B are top plan views of printed circuit boards for mounting semiconductor device packages according to some embodiments, FIG. 2 is a bottom plan view of printed circuit boards for mounting semiconductor packages according to some embodiments, and FIGS. 3A and 3B are sectional views of FIGS. 1A and 1B taken along lines I-I′ and II-II′, respectively.

Referring to FIGS. 1A, 2, and 3A, a printed circuit board 110 for mounting semiconductor device packages includes upper solder balls 112ua provided on the upper surface 110usa, and lower solder balls 112l provided on the lower surface 110ls. The upper solder balls 112ua provided on the upper surface 110usa of the printed circuit board 110 may have a ball array configuration and the same ball out structure of a semiconductor device package (not shown) mounted on the printed circuit board 110. The upper solder balls 112ua may have the ball out structure of a 137-balls fine pitch ball grid array (FBGA).

The lower solder balls 112l provided on the lower surface 110ls of the printed circuit board 110 may have the same ball out structure as a lower board (not shown). The lower solder balls 112l provided on the lower surface 110ls of the printed circuit board 110 may have a standardized ball out structure.

Referring to FIGS. 1B, 2, and 3B, the printed circuit board 110 for mounting semiconductor device packages includes upper solder balls 112ub provided on the upper surface 110usb, and lower solder balls 112l provided on the lower surface 110ls. The upper solder balls 112ub provided on the upper surface 110usb of the printed circuit board 110 may have a ball out structure that is the same as that of a ball array of a semiconductor device package (not shown) mounted on the printed circuit board 110. The upper solder balls 112ub may have the ball out structure of a 137-balls ball grid array package.

The lower solder balls 112l provided on the lower surface 110ls of the printed circuit board 110 may have the same ball out structure as that of a lower board (not shown). The lower solder balls 112l provided on the lower surface 110ls of the printed circuit board 110 may have a standardized ball out structure.

As described with reference to FIGS. 1A through 3B, the printed circuit board 110 for mounting semiconductor device packages of the present invention may have the upper surface (110usa in FIG. 1A and/or 110usb in FIG. 1B) ball out structure corresponding to various types of semiconductor device packages, and a standardized lower surface (110ls in FIG. 2) ball out structure. Therefore, the lower surface ball out structures of various types of the semiconductor device packages may be integrated.

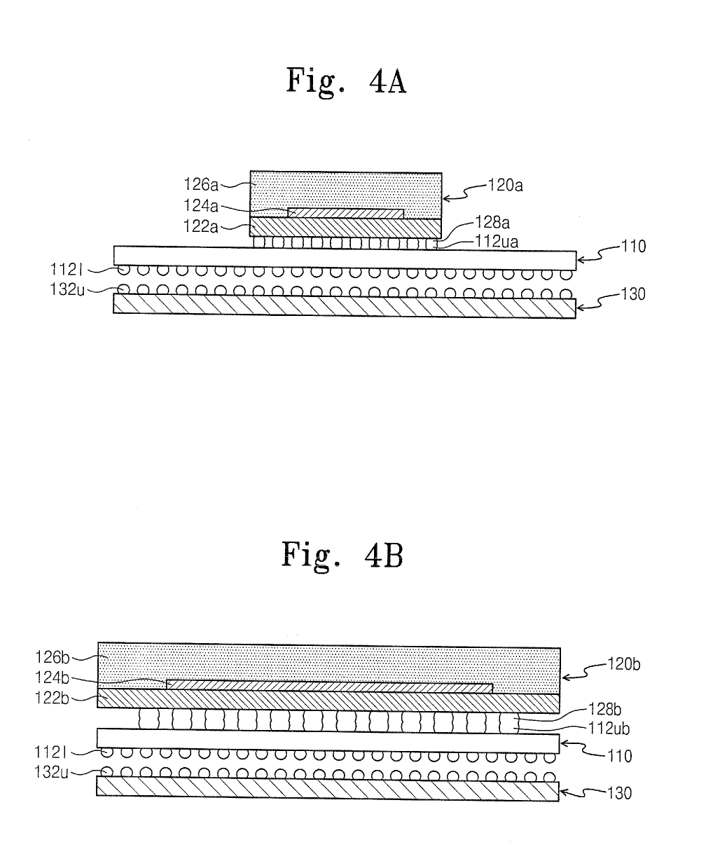

FIGS. 4A and 4B are sectional views of printed circuit boards for mounting semiconductor device packages according to some embodiments.

Referring to FIG. 4A, a semiconductor device package 120a includes a semiconductor chip 124a, a chip printed circuit board 122a (on which the semiconductor chip 124a is mounted), a molding material 126a for sealing the upper portion of the chip printed circuit board 122a, and solder balls 128a provided at a lower surface of the chip printed circuit board 122a. The semiconductor device package 120a may be one selected from a fine pitch ball grid array package, a board on chip (BOC) package, a flip-chip package, a land grid array (LGA) package, and a lead frame package. The semiconductor device package 120a may include at least one semiconductor chip 124a. While not shown, the semiconductor chip 124a may be mounted on a chip printed circuit board 122a in the fine pitch ball grid array package configuration.

The printed circuit board 110 for mounting semiconductor device packages includes upper solder balls 112ua provided on the upper surface (110usa in FIG. 1A), and lower solder balls 112l provided on the lower surface (110ls in FIG. 2).

The solder balls 128a of the semiconductor device package 120a may have the ball out configuration of a 137-balls fine pitch ball grid array package. Accordingly, the upper solder balls 112ua of the printed circuit board 110 may have the same ball out structure as that of the ball array for the 137-balls fine pitch ball grid array package.

The semiconductor device package 120a is mounted on the printed circuit board 110. The semiconductor device package 120a and the printed circuit board 110 may be electrically connected through a connection (112ua and 128a) of the solder balls 128a and the upper solder balls 112ua having the same ball out structure.

The printed circuit board 110, on which the semiconductor device package 120a is mounted, is installed on a test board with a standardized ball out structure. The test board may have the same structure as a lower board 130. The test board may be for testing the electrical characteristics of the semiconductor device package 120a. Therefore, the electrical characteristics testing of the semiconductor device package 120a may be performed through the lower solder balls 112l of the printed circuit board 110. The lower solder balls 112l provided on the lower surface of the printed circuit board 110 may have the same structure as standardized board upper solder balls 132u of the lower board 130.

After the electrical characteristics test of the semiconductor device package 120a is performed, the printed circuit board 110, on which the semiconductor device package 120a is mounted, is mounted on a system board having a standardized ball out structure. The system board may have the same configuration as the lower board 130. The lower solder balls 112l provided on the lower surface of the printed circuit board 110 may have the same structure as the standardized board upper solder balls 132u of the lower board 130.

Referring to FIG. 4B, a semiconductor device package 120b includes a semiconductor chip 124b, a chip printed circuit board 122b (on which the semiconductor chip 124b is mounted), a molding material 126b for sealing the upper portion of the chip printed circuit board 122b, and solder balls 128b provided on the lower surface of the chip printed circuit board 122b. The semiconductor device package 120b may be one selected from a fine pitch ball grid array package, a board on chip package, a flip-chip package, a land grid array package, and a lead frame package. The semiconductor device package 120b may include at least one semiconductor chip 124b. Although not shown, a semiconductor chip 124b may be mounted on the chip printed circuit board 122b in a fine pitch ball grid array package format.

The printed circuit board 110 for mounting semiconductor device packages includes upper solder balls 112ub provided on the upper surface (110usb in FIG. 1B), and lower solder balls 112l provided on the lower surface (110ls in FIG. 2).

The solder balls 128b may have the ball out configuration of a 137-balls ball grid array package. Therefore, the upper solder balls 112ub of the printed circuit board 110 may have the same ball out configuration of the 137-balls ball grid array package.

The semiconductor device package 120b is mounted on the printed circuit board 110. The semiconductor device package 120b and the printed circuit board 110 may be electrically connected through a connection (112ub and 128b) of the solder balls 128b and the upper solder balls 112ub having the same ball out structure.

The printed circuit board 110, having the semiconductor device package 120b mounted thereon, is installed on a test board having a standardized ball out structure. The test board may have the same structure as a lower board 130. The test board may be for testing the electrical characteristics of the semiconductor device package 120b. Accordingly, the electrical characteristics of the semiconductor device package 120b may be tested through the lower solder balls 112l of the printed circuit board 110. The lower solder balls 112l provided on the lower surface of the printed circuit board 110 may have the same structure as the standardized board upper solder balls 132u of the lower board 130.

After the electrical characteristics test of the semiconductor device package 120b is performed, the printed circuit board 110, on which the semiconductor device package 120b is mounted, is mounted on a system board having a standardized ball out structure. The system board may have the same structure as the lower board 130. The lower solder balls 112l provided on the lower surface of the printed circuit board 110 may have the same structure as the standardized board upper solder balls 132u of the lower board 130.

As described with reference to FIGS. 4A and 4B, the printed circuit board 110 for mounting semiconductor device packages according to the present invention may have an upper surface (110usa in FIG. 1A and 110usb in FIG. 1B) ball out structure and a standardized lower surface (110ls in FIG. 2) ball out structure.

Accordingly, the lower surface ball out structures of various types of semiconductor device packages may be integrated. As a result, the various types of the semiconductor device packages are given the same lower surface ball out structure, so that they may be installed on a single standardized test board or mounted on a single standardized system board.

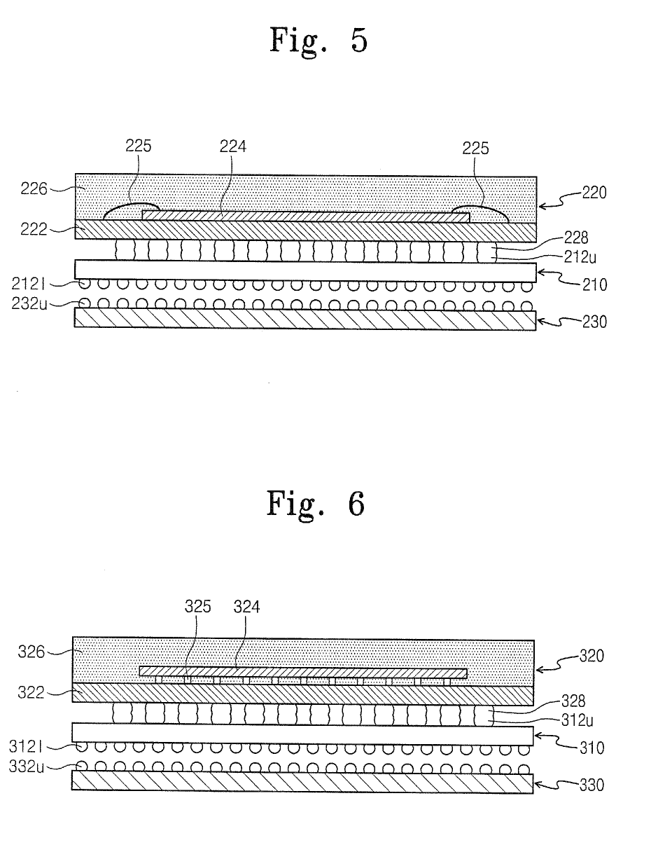

FIGS. 5 through 8 are sectional views of printed circuit boards for mounting semiconductor device packages according to alternate embodiments.

Referring to FIG. 5, a semiconductor device package 220 includes a semiconductor chip 224, a chip printed circuit board 222 (on which the semiconductor chip 224 is mounted), a bonding wire 225 electrically connecting the semiconductor chip 224 to the chip printed circuit board 222, a molding material 226 for sealing the upper portion of the chip printed circuit board 222, and solder balls 228 provided on the lower surface of the chip printed circuit board 222. The semiconductor chip 224 may be mounted on the chip printed circuit board 222 in a board on chip package configuration.

The printed circuit board 210 includes upper solder balls 212u provided on the upper surface thereof, and lower solder balls 212l provided on the lower surface thereof.

The semiconductor device package 220 is mounted on the printed circuit board 210. The semiconductor device package 220 and the printed circuit board 210 are electrically connected through a connection (212u and 228) between the solder balls 228 and the upper solder balls 212u.

The printed circuit board 210, having the semiconductor device package 220 mounted thereon, is installed on a test board having a standardized ball out structure. The test board may have the same structure as a lower board 230. The lower solder balls 212l provided on the lower surface of the printed circuit board 210 may have the same structure as standardized board upper solder balls 232u of the lower board 230. The electrical characteristics of the semiconductor device package 220 may be tested through the lower solder balls 212l of the printed circuit board 210. Thus, the semiconductor device package 220 may be installed on a single standardized test board.

After the electrical characteristics of the semiconductor device package 220 are tested, the printed circuit board 210, on which the semiconductor device package 220 is mounted, is mounted on a system board having a standardized ball out structure. The system board may have the same structure as the lower board 230. The lower solder balls 212l provided on the lower surface of the printed circuit board 210 may have the same structure as the standardized board upper solder balls 232u of the lower board 230. Thus, the semiconductor device package 220 may be mounted on a single standardized system board.

Referring to FIG. 6, a semiconductor device package 320 includes a semiconductor chip 324, a chip printed circuit board 322 (on which the semiconductor chip 324 is mounted), chip solder balls 325 connecting the semiconductor chip 324 to the chip printed circuit board 322, a molding material 326 for sealing the upper portion of the chip printed circuit board 322 on which the semiconductor chip 324 is mounted, and package solder balls 328 provided on the lower surface of the chip printed circuit board 322. The semiconductor chip 324 may be mounted on the chip printed circuit board 322 in the form of a flip-chip package.

The printed circuit board 310 for mounting semiconductor device packages includes upper solder balls 312u provided on an upper surface thereof, and lower solder balls 312l provided on a lower surface thereof.

The semiconductor device package 320 is mounted on the printed circuit board 310. The semiconductor device package 320 and the printed circuit board 310 are electrically connected by a connection (312u and 328) between the solder balls 328 and the upper solder balls 312u.

The printed circuit board 310, on which the semiconductor device package 320 is mounted, is installed on a test board having a standardized ball out structure. The test board may have the same structure as a lower board 330. The lower solder balls 3121 provided on the lower surface of the printed circuit board 310 may have the same structure as the standardized board upper solder balls 332u of the lower board 330. The electrical characteristics of the semiconductor device package 320 may be tested through the lower solder balls 3121 of the printed circuit board 310. Accordingly, the semiconductor device package 320 may be installed on a single standardized test board.

After the electrical characteristics of the semiconductor device package 320 are tested, the printed circuit board 310, on which the semiconductor device package 320 is mounted, is mounted on a system board having a standardized ball out structure. The system board may have the same structure as a lower board 330. The lower solder balls 3121 provided on the lower surface of the printed circuit board 310 may have the same structure as the standardized board upper solder balls 332u of the lower board 330. Accordingly, the semiconductor device package 320 may be mounted on a single standardized system board.

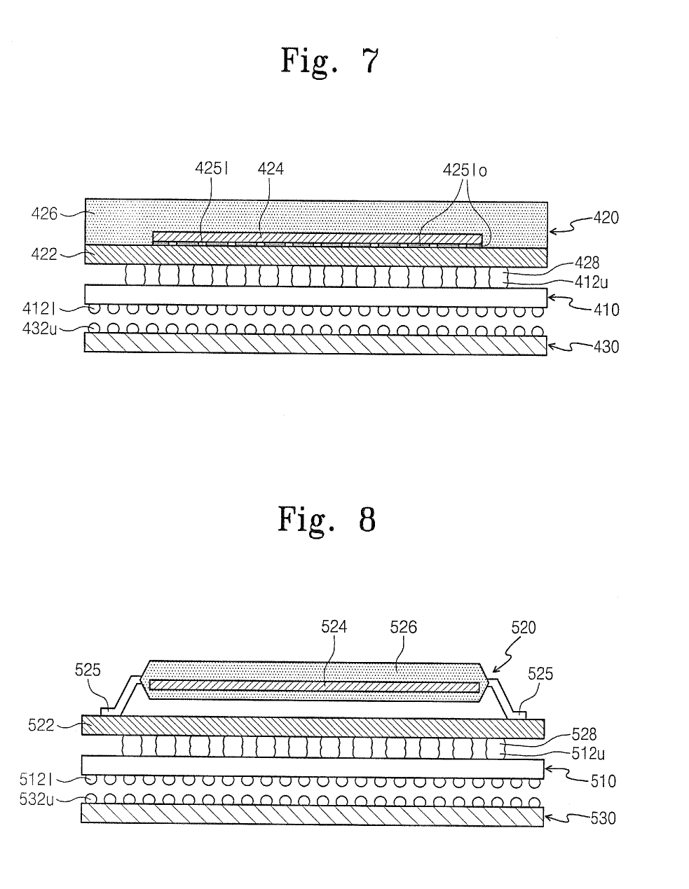

Referring to FIG. 7, a semiconductor device package 420 includes a semiconductor chip 424, a chip printed circuit board 422 (on which the semiconductor chip 424 is mounted), a land 4251 for electrically connecting the semiconductor chip 424 to the chip printed circuit board 422, a molding material 426 for sealing the upper portion of the chip printed circuit board 422 on which the semiconductor chip 424 is mounted, and solder balls 428 provided on the lower surface of the chip printed circuit board 422. The semiconductor chip 424 may be mounted on the chip printed circuit board 422 in the form of a land grid array package. While not described, reference number 425lo is a land open region.

The printed circuit board 410 for mounting semiconductor device packages includes upper solder balls 412u provided on the upper surface thereof and lower solder balls 412l proved on the lower surface thereof.

The semiconductor device package 420 is mounted on the printed circuit board 410. The semiconductor device package 420 and the printed circuit board 410 may be electrically connected through a connection (412u and 428) between the solder balls 428 and the upper solder balls 412u.

The printed circuit board 410, on which the semiconductor device package 420 is mounted, is installed on a test board having a standardized ball out structure. The test board may have the same structure as a lower board 430. The lower solder balls 412l provided on the lower surface of the printed circuit board 410 may have the same structure as the standardized board upper solder balls 432u of the lower board 430. The electrical characteristics of the semiconductor device package 420 may be tested through the lower solder balls 412l of the printed circuit board 410. Accordingly, the semiconductor device package 420 may be installed on a single standardized test board.

After the electrical characteristics of the semiconductor device package 420 are tested, the printed circuit board 410, on which the semiconductor device package 420 is mounted, is mounted on a system board having a standardized ball out structure. The system board may have the same structure as the lower board 430. The lower solder balls 412l provided on the lower surface of the printed circuit board 410 may have the same structure as the standardized board upper solder balls 432u of the lower board 430. Accordingly, the semiconductor device package 420 may be mounted on a single standardized system board.

Referring to FIG. 8, a semiconductor device package 520 includes a semiconductor chip 524, a lead 525 for electrically connecting the semiconductor chip 524 to a chip printed circuit board 522, a molding material 526 for sealing the entire surface of the semiconductor chip 524 and a portion of the lead 525, and solder balls 528 provided on the lower surface of the chip printed circuit board 522. The semiconductor chip 524 may be mounted on the chip printed circuit board 522 in a lead frame package format.

The printed circuit board 510 for mounting semiconductor device packages includes upper solder balls 512u provided on the upper surface thereof and lower solder balls 5121 provided on a lower surface thereof.

The semiconductor device package 520 is mounted on the printed circuit board 510. The semiconductor device package 520 and the printed circuit board 510 may be electrically connected through a connection (512u and 528) between the solder balls 528 and the upper solder balls 512u.

The printed circuit board 510, on which the semiconductor device package 520 is mounted, is installed on a test board having a standardized ball out structure. The test board may have the same structure as a lower board 530. The lower solder balls 512l provided on the lower surface of the printed circuit board 510 may have the same structure as the standardized board upper solder balls 532u of the lower board 530. The electrical characteristics of the semiconductor device package 520 may be tested through the lower solder balls 512l of the printed circuit board 510. Accordingly, the semiconductor device package 520 may be installed on a single standardized test board.

After the electrical characteristics of the semiconductor device package 520 are tested, the printed circuit board 510, on which the semiconductor device package 520 is mounted, is mounted on a system board having a standardized ball out structure. The system board may have the same structure as the lower board 530. The lower solder balls 512l provided on the lower surface of the printed circuit board 510 may have the same structure as the standardized board upper solder balls 532u of the lower board 530. Accordingly, the semiconductor device package 520 may be mounted on a single standardized system board.

Thus, by providing a printed circuit board for mounting semiconductor device packages having an upper surface ball out structure corresponding to semiconductor device packages that include various types of semiconductor chip packages and a standardized lower surface ball out structure, the lower surface ball out structures of the semiconductor device packages of the various types can be integrated. Therefore, the cost and time expended for testing the semiconductor device packages can be reduced, and at the same time, the manufacturing process of printed circuit boards for mounting semiconductor device packages can be simplified and yield increased, and semiconductor device package testing and manufacturing methods using the printed circuit boards can be provided.

As described above, by providing printed circuit boards for mounting semiconductor device packages having upper surface ball out structures corresponding to various types of semiconductor device packages and standardized lower surface ball out structures, the printed circuit boards for mounting semiconductor device packages that can be mounted on a single standardized system board can be provided. Therefore, the lower surface ball out structures of the various types of the semiconductor device packages can be integrated.

Also, by providing the printed circuit boards for mounting semiconductor device packages having the upper surface ball out structures corresponding to the various types of the semiconductor device packages and the standardized lower surface ball out structures, the printed circuit board for mounting semiconductor device packages can be mounted on a single standardized test board. Accordingly, the cost and time expended for testing a semiconductor device package can be reduced.

Furthermore, by providing the printed circuit boards for mounting semiconductor device packages having the upper surface ball out structures corresponding to the various types of the semiconductor device packages and the standardized lower surface ball out structures, the printed circuit board for mounting semiconductor device packages can be provided on a single standardized system board. Thus, a manufacturing method of a semiconductor package with a simplified manufacturing process and an increased yield can be provided.

Although the above described embodiments refer to electrical connections using solder balls, one of ordinary skill in the art will appreciate that any other type of suitable electrical connection could be utilized. Thus, the term solder balls in the above description should be understood to mean any type of electrical connection and/or external terminal.

Also, the above described embodiments refer to printed circuit boards. One of ordinary skill in the art will appreciate that any other type of substrate may be utilized, for example a tape substrate or a lead frame.

Some embodiments provide printed circuit boards for mounting semiconductor device packages. The printed circuit boards include: an upper surface ball out structure configured substantially the same as a ball array of a semiconductor device package mounted on an upper surface of the printed circuit board; and a lower surface ball out structure configured substantially the same as a ball out structure of a lower board, wherein the lower surface ball out structure is a standardized structure.

In some embodiments, the semiconductor device package may be one selected from the group consisting of a fine pitch ball grid array package, a board on chip package, a flip-chip package, a land grid array package, and a lead frame package.

In other embodiments, the lower board may be a test board for testing electrical characteristics of the semiconductor device package.

In still other embodiments, the lower board may be a system board on which the printed circuit board for mounting semiconductor device packages is mounted.

Other embodiments provide methods for testing semiconductor device packages. The methods include: providing a semiconductor device package having a terminal array provided on a lower surface thereof; mounting the semiconductor device package on a substrate, the substrate having an upper surface terminal structure configured substantially the same as the terminal array of the semiconductor device package; installing the substrate on a test board having a standardized terminal structure; and testing the semiconductor device package through a lower surface terminal structure of the substrate, wherein the lower surface terminal structure of the substrate is configured the same as the standardized terminal structure of the test board.

In still other embodiments, the semiconductor device package may be one selected from the group consisting of a fine pitch ball grid array package, a board on chip package, a flip-chip package, a land grid array package, and a lead frame package.

According to some embodiments, each of the terminal array, the upper surface terminal structure, the standardized terminal structure, and the lower surface terminal structure comprises a plurality of solder balls.

Still other embodiments provide methods for fabricating semiconductor device packages. The methods include: providing a semiconductor device package having a terminal array on a lower surface thereof; mounting the semiconductor device package on a substrate having an upper surface terminal structure configured substantially the same as the terminal array of the semiconductor device package; and mounting the substrate on a system board having a standardized terminal structure, wherein the substrate further has a lower surface terminal structure configured substantially the same as the standardized terminal structure of the system board.

In yet other embodiments the semiconductor device package may be one selected from the group consisting of a fine pitch ball grid array package, a board on chip package, a flip-chip package, a land grid array package, and a lead frame package.

According to some embodiments, an apparatus includes a device package including a package terminal array; and a substrate including: an upper terminal array disposed on an upper surface of the substrate; and a lower terminal array disposed on the lower surface of the substrate, wherein a configuration of the package terminal array is substantially the same as a configuration of the upper terminal array, the device package is mounted on the substrate, and a configuration of the lower terminal array is substantially the same as a configuration of a standardized terminal array.

The device package may be one selected from the group consisting of a fine pitch ball grid array package, a board on chip package, a flip-chip package, a land grid array package, and a lead frame package.

Each of the package terminal array, the upper terminal array, the standardized terminal array, and the lower terminal array may comprise a plurality of solder balls.

The apparatus may further comprise a lower board, the lower board having a lower board array, wherein a configuration of the lower board array is substantially the same as the configuration of the standardized terminal array and wherein the substrate is mounted on the lower board. The lower board may be a test board. Alternatively, the lower board may be a system board.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A printed circuit board for mounting a semiconductor device package, the printed circuit board comprising:
an upper surface ball out structure configured substantially the same as a ball array of the semiconductor device package mounted on an upper surface of the printed circuit board; and
a lower surface ball out structure configured substantially the same as a ball out structure of a lower board, wherein the lower surface ball out structure is a standardized structure.

2. The printed circuit board of claim 1, wherein the semiconductor device package is one selected from the group consisting of a fine pitch ball grid array package, a board on chip package, a flip-chip package, a land grid array package, and a lead frame package.

3. The printed circuit board of claim 1, wherein the lower board is a test board for testing electrical characteristics of the semiconductor device package.

4. The printed circuit board of claim 1, wherein the lower board is a system board on which the printed circuit board for mounting the semiconductor device package is mounted.

5. A method for testing semiconductor device packages, comprising:
providing a semiconductor device package having a terminal array on a lower surface thereof;
mounting the semiconductor device package on a substrate, the substrate having an upper surface terminal structure configured substantially the same as the terminal array of the semiconductor device package;
installing the substrate on a test board having a standardized terminal structure; and
testing the semiconductor device package through a lower surface terminal structure of the substrate, wherein the lower surface terminal structure of the substrate is configured substantially the same as the standardized terminal structure of the test board.

6. The method of claim 5, wherein the semiconductor device package is one selected from the group consisting of a fine pitch ball grid array package, a board on chip package, a flip-chip package, a land grid array package, and a lead frame package.

7. The method of claim 5, wherein each of the terminal array, the upper surface terminal structure, the standardized terminal structure, and the lower surface terminal structure comprises a plurality of solder balls.

8. A method of manufacturing a semiconductor device, comprising:
providing a semiconductor device package having a terminal array on a lower surface thereof;
mounting the semiconductor device package on a substrate having an upper surface terminal structure configured substantially the same as the terminal array of the semiconductor device package; and
mounting the substrate on a system board having a standardized terminal structure, wherein the substrate further includes a lower surface terminal structure configured substantially the same as the standardized terminal structure of the system board.

9. The method of claim 8, wherein the semiconductor device package is one selected from the group consisting of a fine pitch ball grid array package, a board on chip package, a flip-chip package, a land grid array package, and a lead frame package.

10. The method of claim 8, wherein each of the terminal array, the upper surface terminal structure, the standardized terminal structure, and the lower surface terminal structure comprises a plurality of solder balls.

11. An apparatus, comprising:
a device package including a package terminal array; and
a substrate including:
an upper terminal array disposed on an upper surface of the substrate; and
a lower terminal array disposed on the lower surface of the substrate,
wherein a configuration of the package terminal array is substantially the same as a configuration of the upper terminal array, the device package is mounted on the substrate, and a configuration of the lower terminal array is substantially the same as a configuration of a standardized terminal array.

12. The apparatus of claim 11, wherein the device package is one selected from the group consisting of a fine pitch ball grid array package, a board on chip package, a flip-chip package, a land grid array package, and a lead frame package.

13. The apparatus of claim 11, wherein each of the package terminal array, the upper terminal array, the standardized terminal array, and the lower terminal array comprises a plurality of solder balls.

14. The apparatus of claim 11, further comprising a lower board, the lower board having a lower board array, wherein a configuration of the lower board array is substantially the same as the configuration of the standardized terminal array and wherein the substrate is mounted on the lower board.

15. The apparatus of claim 14, wherein the lower board is a test board.

16. The apparatus of claim 14, wherein the lower board is a system board.
